(19) United States
(12) Patent Application Publication
(10) Pub. No.: US 2016/0049914 A1
(43) Pub. Date: Feb. 18, 2016

(54) AUDIO SIGNAL SIZE CONTROL METHOD AND DEVICE

(71) Applicant: INTELLECTUAL DISCOVERY CO., LTD., Seoul (KR)

(72) Inventors: Byeong Ho CHOI, Yongin-si (KR); Je Woo KIM, Seongnam-si (KR); Hwa Seon SHIN, Yongin-si (KR); Choong Sang CHO, Seongnam-si (KR)

(73) Assignee: Intellectual Discovery Co., Ltd., Seoul (KR)

(21) Appl. No.: 14/778,875

(22) PCT Filed: Mar. 20, 2014
(86) PCT No.: PCT/KR2014/002365

§ 371 Date: Sep. 21, 2015

(30) Foreign Application Priority Data
Mar. 21, 2013 (KR) 10-2013-0030136
Apr. 3, 2013 (KR) 10-2013-0036491

(51) Int. Cl. H03G 3/20; H04H 60/58; H04H 60/07

(52) U.S. Cl. CPC H03G 3/20; H04H 60/07; H04H 60/58

(57) ABSTRACT

An audio signal size control method is disclosed. The control method comprises the steps of: calculating, by using an input audio signal, a first band gain for compensating for normalization degradation as a result of normalizing an input audio signal size to a target audio signal size; applying the calculated first band gain to the input audio signal; and normalizing the audio signal, to which the calculated first band gain has been applied.

### TECHNICAL FIELD

The present invention relates to a method and apparatus for adjusting an audio signal size played back in multimedia.

### BACKGROUND ART

People are placed in various environments and exposed to various sounds in everyday life. Sounds exposed to people are generated by various reasons. As shown in FIG. 1, the sounds include an environment noise that generates uneasiness when a person hears the noise, a multimedia sound and music that makes a person pleasant, and a sound generated when people exchange dialogues and information.

Several sounds around people may inflict pain on a person, may make delight a person, or may provide various pieces of information to people depending on the size and type of a sound. Such a reason lies in that the size and intensity of a sound becomes a valuable numerical value which defines the degree of acoustic fatigue and the physical properties of the sound because the hearing structure of a person recognizes the sound through the sound pressure level of the sound transferred through air.

A sound size (loudness), that is, one of methods for evaluating a sound, is a subjective sound size recognized by the acoustic system of a person when any sound is delivered to a person's ear. The intensity of a sound is power of a sound, that is, the intensity of an objective sound delivered to the acoustic system of a person. In general, the intensity of a sound is measured as a well-known decibel. In general, the intensity of a sound of a dialogue between people is 60˜70 dB, and the intensity of a sound in the roadside having heavy traffic and severe noise is about 80 dB. In general, people feel relaxed about in a 70 dB range.

Referring to FIG. 1, a method and opportunity in which modern people encounter audio are gradually increased. With the development of portable multimedia audio devices, people become able to enjoy required multimedia content and music anywhere and at any situation. In particular, in audio, as MP3 (MPEG-1 Layer III) emerged and the Internet was commercialized in the late 1990s, people have become able to easily download a digital sound source compressed in MP3 through the Internet and hear the downloaded digital sound source.

A commercial audio sound source market has been fused with the popularization of multimedia devices and rapidly expanded. In order to attract people's interest as competitiveness becomes severe in the field, a ratio of a difference (dynamic range) between a playable maximum sound and minimum sound of an audio sound source has been abruptly reduced and a maximum value of a waveform has been increased, so an audio sound size has been significantly increased. This become further intensified in the thought “as an audio sound size is increased, people may recognize a corresponding audio as better music.”

FIG. 2(A) shows the waveform of music (pops) in 1970, and FIG. 2(B) shows the waveform of K-pops in 2011. From FIG. 2, it may be seen that the dynamic range of music recorded a long time again is wider than that of a recently issued sound source. It may be seen that the waveform of a K-pops sound source that has been recently globalized reaches a maximum value or exceeds the maximum value.

Accordingly, there is a need for a technology for accurately measuring the sound size of an audio and adjusting a sound size in a multimedia device and for a technology for adjusting an audio sound size.

### DISCLOSURE

### Technical Problem

An object of the present invention is to provide an apparatus and method for adjusting an audio signal size, which compensate for deterioration attributable to the normalization of an audio signal size.

### Technical Solution

A method of adjusting an audio signal size in accordance with an embodiment of the present invention for accomplishing the object includes steps of calculating a first band gain for compensating for normalization deterioration attributable to the normalization of the size of an input audio signal into the size of a target audio signal using the input audio signal, applying the calculated first band gain to the input audio signal, and normalizing an audio signal to which the calculated first band gain has been applied.

Furthermore, the method may further include steps of receiving the broadcasting signal of a broadcasting program, detecting program genre information in the received broadcasting signal, and calculating a second band gain corresponding to the detected program genre information, wherein the step of applying the calculated first band gain to the input audio signal may include applying the calculated first band gain and the second band gain to the input audio signal.

Furthermore, the step of normalizing the audio signal may include steps of measuring a first audio signal size which is the size of an audio signal to which the first and the second band gains have been applied, scaling the audio signal to which the first and the second band gains have been applied using a preset initial Peek weighting value and measuring a second audio signal size which is the size of the scaled audio signal, and adjusting the size of the audio signal to which the first and the second band gains have been applied using the first audio signal size, the second audio signal size, and the target audio signal size.

Meanwhile, a method of adjusting an audio signal size in accordance with an embodiment of the present invention for accomplishing the object includes steps of receiving a broadcasting signal, detecting program genre information in the received broadcasting signal and calculating a third band gain corresponding to the detected program genre information, detecting an audio signal in the received broadcasting signal and calculating a fourth band gain for normalizing the size of the detected audio signal into the size of a target audio signal, and applying the calculated third band gain and fourth band gain to the detected audio signal.

Furthermore, the step of applying the calculated third band gain and fourth band gain to the detected audio signal may include a step of performing multiplication operation for multiplying the calculated third band gain and the calculated fourth band gain and applying a result of the multiplication operation to the audio signal.

### Advantageous Effects

In accordance with various embodiments of the present invention, compensation filtering can be performed by taking into consideration that a person's hearing sense is sensitive to a low band and insensitive to a high band and that a deviation of an audio signal size is reduced due to normalization. Accordingly, adverse effects attributable to the normalization of an audio signal size, such as a problem in that the configuration of an audio signal becomes flat and a problem in that a volume deviation edited/modified by an audio editor disappears or reduces, in a normalized and output audio signal can be solved.

### DESCRIPTION OF DRAWINGS

FIG. 1 is a diagram illustrating various hearing fatigue main causes generated in everyday life.

FIG. 2 is a diagram showing examples of the waveforms of audio signals.

FIG. 3 is a diagram illustrating a distortion phenomenon attributable to audio clip data clipping.

FIG. 4 is a diagram illustrating a hearing loss attributable to audio and noises.

FIG. 5 is a diagram illustrating the normalization of the audio signal size of a digital broadcasting program.

FIG. 6 is a diagram showing a method of measuring the size of an audio signal.

FIG. 7 is a graph showing an example of the frequency response characteristics of a pre-filter.

FIG. 8 is a graph showing an example of the frequency response characteristics of an RLB filter.

FIG. 9 is a diagram illustrating an example of the structure of a broadcasting system for a recorded and previously produced broadcasting program.

FIG. 10 is a diagram showing a first embodiment of a method of adjusting an audio signal size.

FIG. 11 is a detailed diagram illustrating the first embodiment of the method of adjusting an audio signal size.

FIG. 12 is a diagram showing a basic structure of the computation of a loudness control ratio based on a peak value for adjusting an audio signal size.

FIG. 13 is a diagram showing an example of the structure of a real-time broadcasting system.

FIG. 14 is a diagram showing a second embodiment.

FIG. 15 is a detailed diagram illustrating the second embodiment.

FIG. 16 is a diagram illustrating a method in which a live LD control step has been added to the last stage of the first embodiment, the second embodiment.

FIG. 17 is a diagram showing a third embodiment of a method of compensating for the deterioration of sound quality attributable to the adjustment of the size of an audio signal.

FIG. 18 is a diagram showing a fourth embodiment of a method of adjusting an audio signal size in a terminal.

FIG. 19 is a detailed flowchart illustrating a method of adjusting an audio signal size in an apparatus for adjusting an audio signal size in accordance with a first embodiment of the present invention.

FIG. 20 is a diagram illustrating a method of measuring the size of an audio signal to which an audio gating method described in ITU-R 1770-2 has been added.

FIG. 21 is a diagram illustrating gate handover in order to describe a method of adjusting an audio signal size in accordance with a fifth embodiment of the present invention.

FIG. 22 is a diagram illustrating the method of adjusting an audio signal size in accordance with the fifth embodiment of the present invention.

FIG. 23 is a diagram illustrating linear interpolation, that is, an example of interpolation in accordance with the fifth embodiment of the present invention.

FIG. 24 is a diagram showing an example of information provided in half automatic loudness control mode of the second embodiment of the present invention.

FIG. 25 is a diagram showing a method of calculating a recommended control factor that belongs to information provided in half automatic loudness control mode of the second embodiment of the present invention.

FIG. 26 is a diagram showing a method of adjusting an audio signal size in automatic loudness control mode of the second embodiment of the present invention.

FIG. 27 is a diagram showing a method of designing a mapping curve for calculating a mapping audio signal size (mapped LKFS) according to FIG. 26.

FIG. 28 is a detailed diagram showing one of methods of adjusting an audio signal size in accordance with a third embodiment of the present invention.

FIG. 29 is a detailed diagram showing the other of the methods of adjusting an audio signal size in accordance with the third embodiment of the present invention.

FIG. 30 is a detailed diagram of FIG. 29.

FIGS. 31 to 33 are diagrams showing a comparison between the waveform of an input audio signal and the waveform of a normalized audio signal.

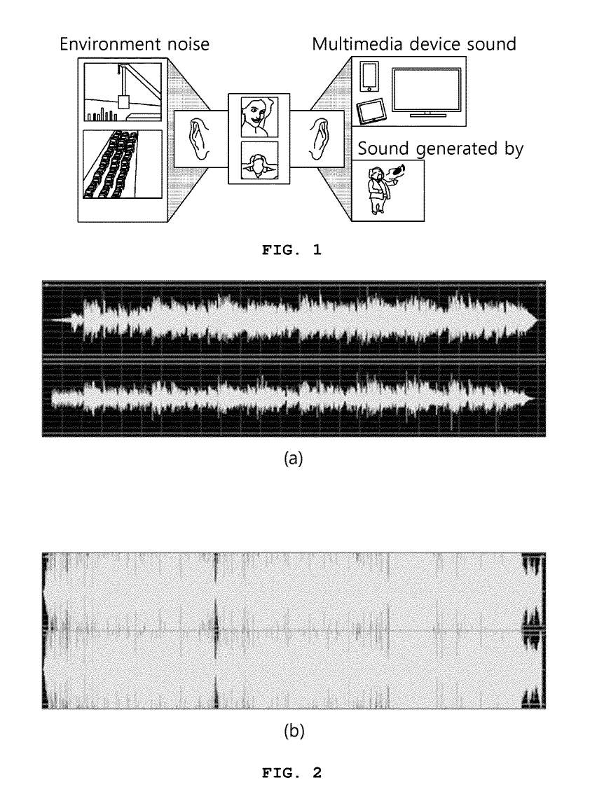

### MODE FOR INVENTION

The following contents illustrate only the principle of the present invention. Although devices have not been clearly described or illustrated in this specification, those skilled in the art may implement various devices that implement the principle of the present invention and are included in the concept and scope of the present invention. Furthermore, it should be understood that in principle, conditional terms and embodiments listed in this specification are evidently intended only in order for the concept of the present invention to be understood and the scope of the present invention is not restricted by the specially listed embodiments and states.

Furthermore, it is to be understood that all the detailed descriptions that list specific embodiments in addition to the principle, aspects, and embodiments of the present invention are intended to include the structural and functional equivalents of such matters. Furthermore, it should be understood that the equivalents include equivalents to be developed in the future, that is, all devices invented to perform the same function by substituting some elements, in addition to known equivalents.

Accordingly, it should be understood that a block diagram of this specification, for example, is indicative of a conceptual viewpoint of an exemplary circuit that materializes the principle of the present disclosure. Likewise, it should be understood that all flowcharts, state change diagrams, and pseudo code may be substantially represented in computer-readable media and are indicative of various processes that are executed by computers or processors irrespective of whether the computers or processors are evidently illustrated.

The functions of processors or the functions of various devices illustrated in the drawings that include function blocks illustrated as a similar concept may be provided by the use of hardware capable of executing software in relation to proper software, in addition to dedicated hardware. When being provided by a processor, the function may be provided by a single dedicated processor, a single sharing processor, or a plurality of separated processors, and some of them may be shared.

Furthermore, a processor, control, or a term suggested as a similar concept thereof, although it is clearly used, should not be construed as exclusively citing hardware having the ability to execute software, but should be construed as implicitly including Digital Signal Processor (DSP) hardware, or ROM, RAM, or non-volatile memory for storing software without restriction. The processor, control, or term may also include known other hardware.

In the claims of this specification, an element represented as means for executing a function written in a detailed description has been intended to include all methods of performing a function including all types of software which include a combination of circuit elements configured to perform the function or firmware/microcode, and is combined with a proper circuit configured to execute the software in order to perform the function. It is to be understood that any means capable of providing the function is equivalent with a thing checked from this specification because functions provided by variously listed means are combined and the present disclosure defined by the claims is combined with a method required by the claims.

The above objects, characteristics, and merits will become more apparent from the following detailed description taken in conjunction with the accompanying drawings, and thus those skilled in the art to which the present invention pertains may readily implement the technical spirit of the present invention. Furthermore, in describing the present invention, a detailed description of a known art related to the present invention will be omitted if it is deemed to make the gist of the present invention unnecessarily vague.

A preferred embodiment of the present invention is described in detail with reference to the accompanying drawings.

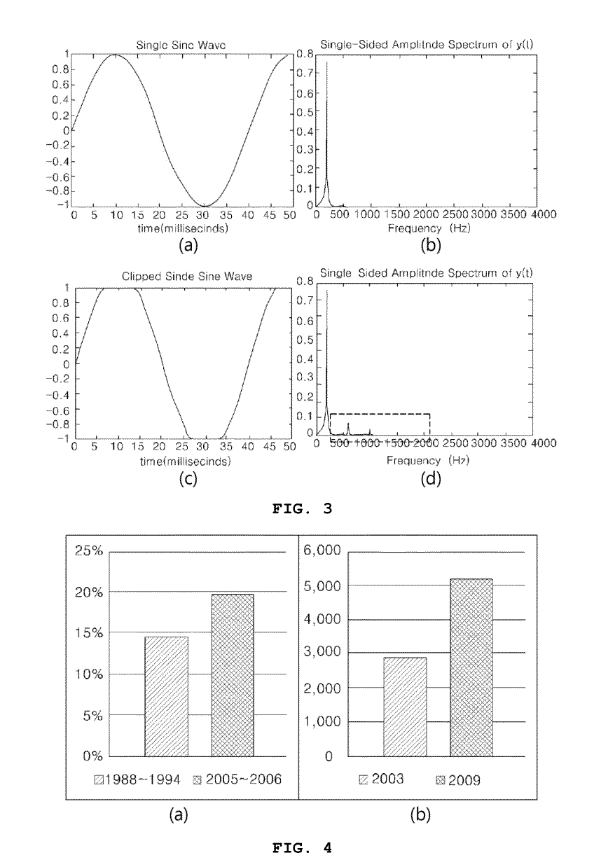

FIG. 3 is a diagram illustrating a distortion phenomenon attributable to audio clip data clipping.

If the waveform of a sound source exceeds a permissible data resolution range in digital data, the waveform of the sound source is clipped, and this phenomenon is audio data clipping.

FIG. 3(A) shows a sine wave not including clipping, (B) shows a waveform frequency characteristics not including clipping, (C) shows a sine wave including clipping, and (D) shows a waveform frequency characteristics including clipping.

Referring to FIG. 3, the audio data clipping phenomenon distorts an audio signal. When the frequency characteristics of the simple sine waveform (FIG. 3(B)) are compared with the frequency characteristics of the clipped sine waveform (FIG. 3(D)), it may be seen that a signal distortion component not present in a sine waveform not including clipping as in a region indicated by a dotted line of FIG. 3(D) is generated by audio data clipping.

Meanwhile, a problem attributable to an increase of an audio sound size is amplified by the popularization of a portable multimedia device. Teenagers who currently have a greatly increased audio hearing time due to multimedia devices continue to be exposed to a sound source having a very large audio sound size.

From FIG. 4, it may be seen that the hearing ability of teenagers in the United States was greatly lost when portable multimedia devices were popularized in the middle 2000s compared to prior to the emergence of a portable multimedia device based on MP3 in the early 1990s.

Furthermore, it may be seen that noise type hearing loss patients in Korea was increased about 50% compared to the early and late 2000s and hearing fatigue attributable to multimedia devices and noise environments exceeds a threshold and affects the deterioration of a hearing function.

Accordingly, in order for people to safely live and pleasantly enjoy audio and music during their lifetime, there is a need for a task for lowering hearing fatigue attributable to audio.

To this end, an embodiment of the present invention relates to a method of accurately measuring an audio sound size and adjusting a sound size in a multimedia device.

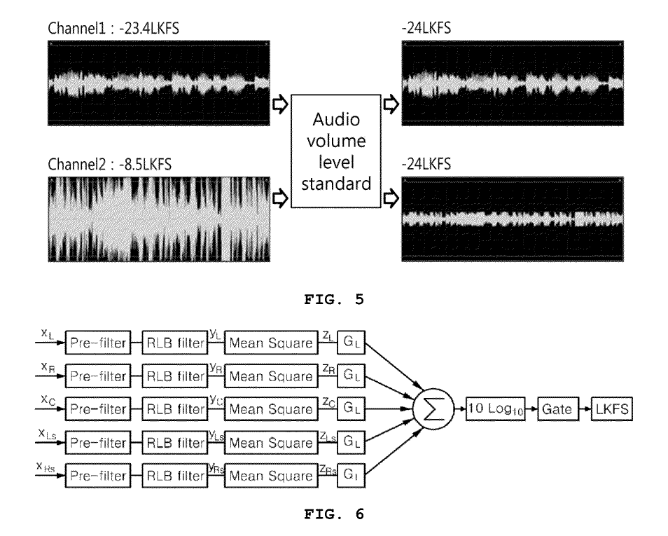

FIG. 5 is a diagram illustrating the normalization of the audio signal size of a digital broadcasting program.

In Korea, an effort to reduce an audio signal size (loudness) difference between broadcasting stations and pieces of content through the amendment of the Broadcasting Act is in progress. Today, programs transmitted by broadcasting have a great difference between broadcasting companies and pieces of broadcasting content.

FIG. 5 shows that the audio signal sizes (e.g., Channel 1:−23.4 LKFS and Channel 2: −8.5 LKFS) of two types of music content have a significant difference. Such a difference causes significant inconvenience to broadcasting viewers. In order to overcome such a problem, a standardization task under the name of a “digital broadcasting program volume level criterion” is in progress in the PG803 WG8034 subsidiary of the TTA.

The object of the standardization is to prepare a criterion on which a channel/broadcasting program having a significant size difference is made to have a normalized audio signal size (e.g., Channel1: −24 LKFS and Channel2: −24 LKFS) by controlling the channel/broadcasting program based on a standardized volume standard, as shown in FIG. 5.

The standardization may be associated with the Broadcasting Act. If the importance and usability of the standard are very high, the standard may propose an audio signal criterion and standard suitable for a local situation based on ITU-1770-1/2, that is, an internal audio signal size measurement standard. Accordingly, techniques which may help to comply with the audio signal criterion and standard and analysis of a current digital broadcasting signal size will be performed.

FIG. 6 is a diagram showing a method of measuring the size of an audio signal.

Research on a method of measuring the size of an audio signal was started in the middle 2000s. ITU issued ITU-R BS. 1770-1, that is, a standard for the measurement of an audio signal size, in the year of 2006. ITU-R BS. 1770-2 to which a gating method was added was issued in the year of 2011.

The issued standard proposed only a method of measuring the size of an audio signal and a true peak measurement method, and a part regarding control of an audio signal size has not been performed. So far, a part regarding a method of adjusting an audio signal size has not been standardized.

In the method of measuring the size of an audio signal standardized by the ITU-R, measurement is performed through a loudness, K weighting value, relative to nominal full scale (LKFS), such as that shown in FIG. 6.

The first module (pre-filter) of an algorithm is formed of a secondary IIR filter in order to take into consideration an acoustic influence according to the head of a person.

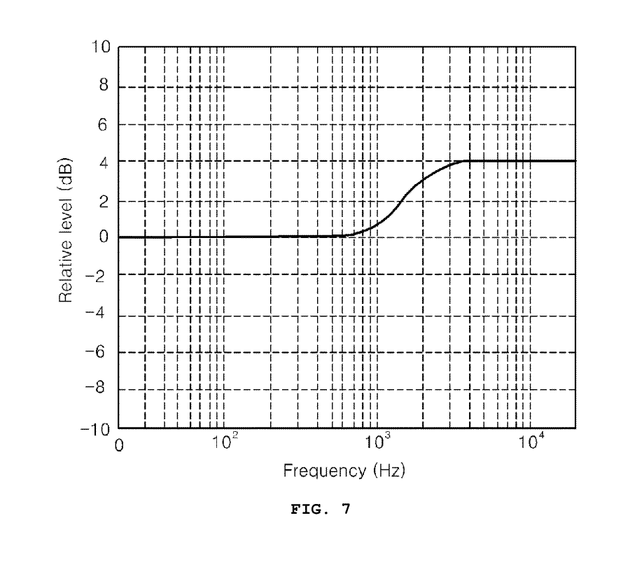

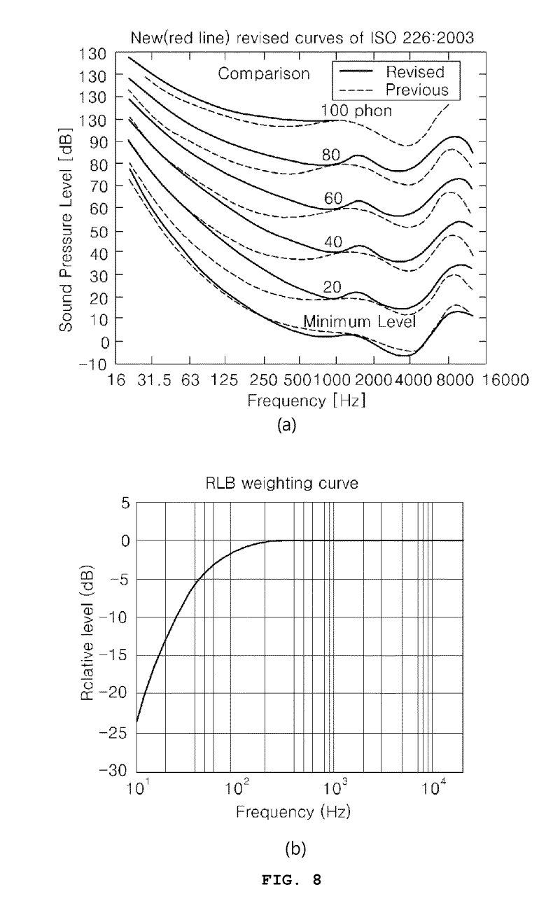

FIG. 7 is a graph showing an example of the frequency response characteristics of the pre-filter.

The frequency characteristics of the pre-filter remove a region of 1 kHz or less and permits a pass in a region of 1 kHz or more based on about 1 kHz, as shown in FIG. 7. The filter coefficient of 48 kHz data that is used in general is provided by ITU-R BS. 1770-1 based on the head model of a spherical shape.

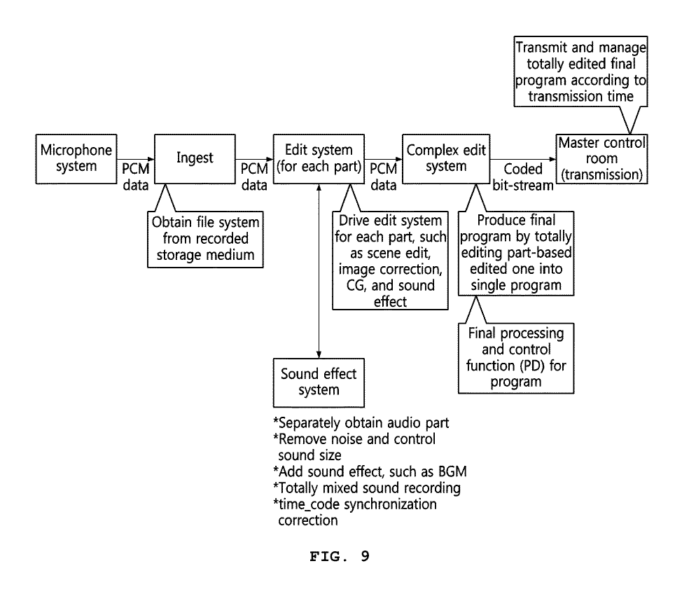

FIG. 8 is a graph showing an example of the frequency response characteristics of an RLB filter.

In a second module (RLB filter), a weighting filter based on a human's acoustic characteristic is applied. The filter is based on a characteristic in which a person's hearing has different sensitivity in the frequency region of an input sound, as shown in FIG. 8(A).

For example, FIG. 8(A) shows that a person recognizes about 20 dB in 250 Hz and about 1 dB in 1 kHz based on a minimum level as the same audio sound size. Accordingly, a band type weighting filter has been designed so that a filter response for taking into consideration the hearing of a person has a filter response similar to a case where the same audio sound size contour line defined in ISO 226 is inversely applied as shown in FIG. 8(B).

In the designed weighting filter, the weighting value of a low frequency region was reduced, but a region of 1 kHz or more had a relatively high weighting value compared to the low frequency region. Furthermore, in order to simplify the weighting filter, a region of 1 kHz or more was flatly designed. The RLB weighting filter has a secondary IIR filter structure and provides a filter coefficient for 48 kHz data through the ITU-R document.

Results passing through the weighting filter are converted as in the following equation in the mean-square energy module of FIG. 6.

$${z}_{i} = \frac{1}{T} {\int }_{0}^{T} {y}_{i}^{2} \qquad [ Equation 1 ]$$

Energy to which a weighting value has been applied is summed by applying a weighting value for each channel to energy of each channel as in the following equation and then converted in decibels by applying the sum to a log equation. A loudness, K weighting value, relative to nominal full scale (LKFS) is used as a unit for a sound size obtained by the following equation.

$$Loudness = - 0.691 + 10 {log}_{10} {\sum }_{i}^{N} {G}_{i} \times {z}_{i} LKFS \qquad [ Equation 2 ]$$

In Equation 2, N is the number of channels, and G is the weighting value of a channel.

In order to verify whether the designed audio sound size measurement method based on ITU has been accurately designed, a sound size measurement value of −3.01 LKFS needs to be output when a sine waveform of 0 dB and 1 kHz is received.

Existing research on the size of an audio signal may be basically divided into two. The first is the development of an objective audio signal size measurement algorithm that is close to an audio volume level which his acoustically recognized by a person as in ITU-R1770-1.

In the second, in a prior art, the size of an audio signal was not normalized and transmitted. Accordingly, research on automatic control of an audio signal size was carried out when audio files having different sizes were received because an audio file and a sound source heard by a person have different volumes.

In each country, in order to overcome a problem according to the size of an audio signal, the size of an audio signal is measured based on ITU-1770-1/2, and a reference value and error range for the normalization of an audio signal size are proposed based on the measured size. Today, in Japan, such a method is actively handled, but in other countries, such a method is in the early stage or partially applied to only parts, such as commercial advertisements.

That is, contents included in the standardization and regulation acts define a normalization criterion and error range and an application range, but do not suggest a method for complying with such a standard. That is, only an object that must be achieved was suggested, and a method for complying with the standard has not been proposed.

Meanwhile, an audio gating method was added to the ITU-R audio signal size measurement method amended on March, 2011. Audio gating is a method of measuring an audio volume except a part having a low audio volume.

A block for audio volume measurement gating is one cycle, and 75% of the block overlaps with a neighbor block. Furthermore, a sample that does not satisfy a block size in the last of a file is not measured.

First, the mean square of a block unit is calculated as in the following equation.

$${z}_{ij} = \frac{1}{{T}_{g}} {\int }_{{T}_{g} \cdot ( f \cdot step )}^{{T}_{g} \cdot ( j \cdot step + 1 )} {y}_{i}^{2} d t where step = 1 - overlap \\ and j ∈ ( 0 , 1 , 2 , … , \frac{T - {T}_{g}}{{T}_{g} \cdot step} ) \qquad [ Equation 3 ]$$

The audio volume of each gated block is calculated as follows based on the following existing equation.

$${l}_{i} = - 0.691 + 10 {log}_{10} {\sum }_{i} {G}_{i} \cdot {z}_{ij} \qquad [ Equation 4 ]$$

If gating is applied to each block, in ITU-R 1770-2, only a signal of −70 LKFS or higher is taken into consideration, and the LKFS of a signal to which gating has been applied is measured as in the following equation.

$$Gated loudness {L}_{KG} = - 691 + 10 {log}_{10} {\sum }_{i} {G}_{i} \cdot ( \frac{1}{\vert {J}_{g} \vert} \cdot {\sum }_{{J}_{g}} {z}_{i , j} ) \\ Where {J}_{g} = \{ i : {l}_{j} > {T}_{r} \} \\ {L}_{r} = - 691 + 10 {log}_{10} {\sum }_{i} {G}_{j} \cdot ( \frac{1}{\vert {J}_{g} \vert} \cdot {\sum }_{{J}_{g}} {z}_{i , j} ) - 10 where {J}_{g} = \{ i : {l}_{j} > - 70 LKFS \} \qquad [ Equation 5 ]$$

In the amended method, if the existing pre-filter and RLB filter are used in the same manner, a method of verifying the accuracy of an algorithm is also the same.

When the aforementioned contents are taken into consideration, contents included in the standardization and regulation acts so far define a normalization criterion, an error range, and an application range, but do not clearly disclose a method for complying with the standard.

Accordingly, in accordance with a first embodiment of the present invention to be described later, the size of an audio signal can be controlled so that it complies with a standard with respect to a recorded and previously produced broadcasting program.

Furthermore, in accordance with a second embodiment of the present invention to be described later, the size of an audio signal can be controlled so that it complies with a standard with respect to a real-time/live-obtained broadcasting program.

Furthermore, in accordance with a third embodiment of the present invention to be described later, the size of an audio signal can be controlled while minimizing the deterioration of hearing audio sound quality attributable to the normalization of an audio signal size.

Furthermore, in accordance with the fourth embodiment of the present invention to be described later, a new audio control function in a terminal (TV, a smart phone) can be provided by taking into consideration the normalization of an audio signal size.

FIG. 9 is a diagram illustrating an example of the structure of a broadcasting system for a recorded and previously produced broadcasting program.

Referring to FIG. 9, audio data obtained on the spot is stored in an Ingest server. The stored file is delivered to an edit system. In the edit system, edits for each part, such as known video/audio effects, audio noise removal, and video/audio synchronization, are performed.

The data on which the edits for each part have been performed is finally processed in a complex edit system. A master control room sends an edited broadcasting program. In view of such a structure, a task for normalizing the audio signal size of a recorded and previously produced broadcasting program attributable to the regulation of an audio signal size may be performed in the edit system and the complex edit system. Preferably, a step of producing a file may be performed as the post task of the edit system because audio data is independently controlled by the edit system.

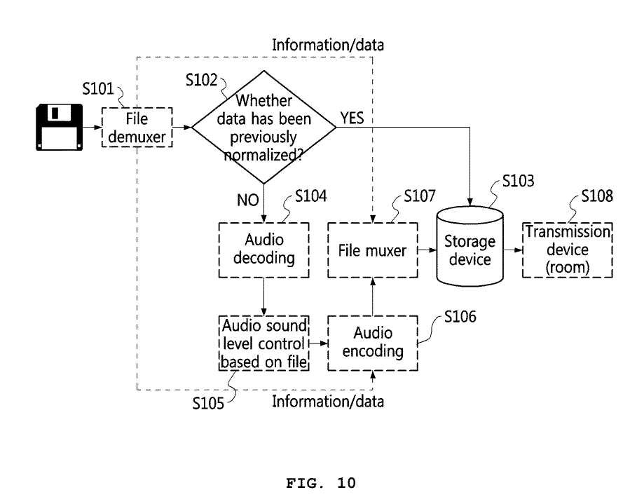

FIG. 10 is a diagram showing a first embodiment of a method of adjusting an audio signal size.

In the case of an existing recorded broadcasting program file, the stored file needs to be analyzed and the normalization of an audio signal size needs to be performed. Accordingly, referring to FIG. 10, a demultiplexer may select audio data by demuxing an existing recorded broadcasting program file (S101).

Furthermore, a normalization determination unit may determine whether the audio data has been previously normalized (S102). In this case, the normalization means normalizing an audio signal size by adjusting the audio signal size according to a standardized audio signal size standard as in FIG. 5.

If the audio data has been previously normalized (S102: Y), the audio data on which the normalization has been performed may be stored in a storage device (S103).

If the audio data has not been previously normalized (S102: N), an audio decoder may decode the audio data (S104). Furthermore, an audio signal size controller may perform the normalization of the audio signal size using the decoded audio data (S105). Furthermore, an audio encoder may encode the normalized audio data (S106).

Meanwhile, a multiplexer may multiplex the encoded audio data with other data not selected in the demultiplexer (S107). Accordingly, the storage device may store audio data whose audio signal size has been normalized (S103).

The data stored in the storage device may be provided to a transmission room (S108).

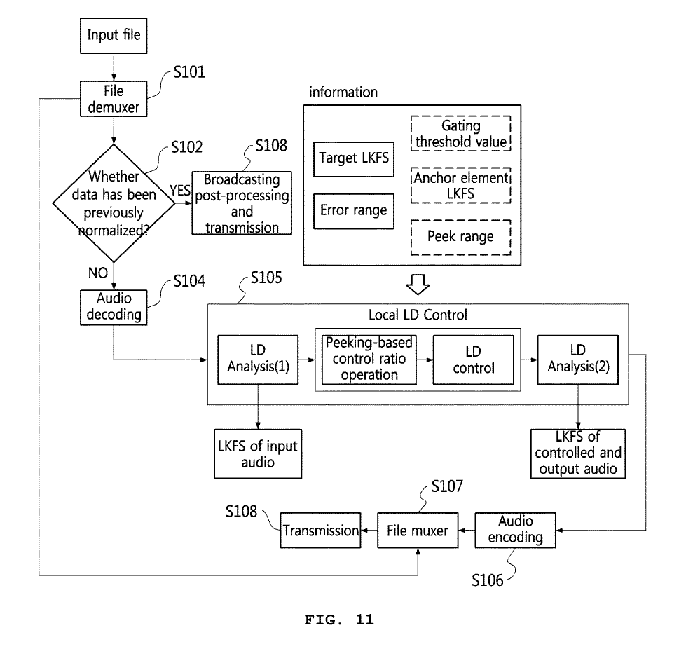

In this case, a detailed operation of the audio signal size controller is described in detail with reference to FIGS. 11 and 12.

Meanwhile, dotted blocks shown in FIG. 10, for example, step S101, step S104, step S106, and step S107 may be omitted according to circumstances depending on the format of audio data. For example, steps S104 and S106 may be omitted depending on whether audio data has been compressed.

In accordance with the first embodiment of the present invention, in order for the audio volume of a recorded and previously produced broadcasting program to be controlled so that the audio volume complies with an audio volume standard, first, a step of producing the broadcasting program is analyzed, and an essential audio volume may be measured and controlled according to audio volume regulations.

FIG. 11 is a detailed diagram illustrating the first embodiment of the method of adjusting an audio signal size. FIG. 12 is a diagram showing a basic structure of the computation of a loudness control ratio based on a peak value for adjusting an audio signal size. In describing FIGS. 11 and 12 hereinafter, a detailed description of the parts described with reference to FIG. 10 is omitted, and the remaining parts are described.

Referring to FIG. 11, control information may be provided in order to control a recorded broadcasting program.

First, there may be provided target audio signal size (target LKFS) values and audio signal size error ranges defined by several countries according to their regulations and standards. In general, U.S.A/Japan have a range of 24 LKFS (target LKFS)+/−2 dB (error range), and Europe has a range of 23 LKFS (target LKFS)+/−1 dB (error range).

A part related to audio gating was first mentioned in ITU-R 1770-2 and is a method of measuring an LKFS for each block by applying an overlap and shift method, considering parts having a low block LKFS as silence, and not using the mean value of such parts.

In the case of the ATSC of U.S.A, an AC-3 audio system is used, and a “dialnorm” parameter is stored as a metadata parameter. An acoustic audio signal size for an anchor element is inserted into the dialnorm parameter. That is, the acoustic audio signal size of a reference point or element is inserted into the part.

The anchor element is indicative of the standard audio signal size of the center of a current broadcasting program. The broadcasting program is finally balanced based on the anchor element. Furthermore, LKFS values are stored in the dialnorm parameter. The dialnorm parameter has a variable space of 5 bits and may store −1˜−31 LKFS values.

Meanwhile, in order to measure an audio signal size based on ITU-R, two filters need to be applied. Accordingly, although an audio signal size conversion value is extracted by inversely calculating a difference value between a measured LKFS and a target LKFS according to the LKFS measurement equation, an accurate value is unable to be obtained because there is an influence on the two filters.

In order to overcome such a problem, in accordance with the first embodiment of the present invention, an algorithm for obtaining an audio signal size conversion weighting value factor suitable for a required target LKFS can be provided by designing a method using a Peek value.

As described above, an accurate loudness (LD) control ratio is unable to be calculated using only the LKFS (original) and target LKFS of input audio for the aforementioned reason.

Accordingly, in accordance with the first embodiment of the present invention, in order to calculate an LD control ratio in which the two filters are taken into consideration, a Peek-based control ratio may be calculated using a Peeking method. The Peeking method may mean a method of obtaining a Peeked LKFS by performing loudness control on an audio signal using a Peek-based control ratio. That is, the audio signal size controller may receive input audio data (S105-1), a Peek weighting value (e.g., 0.9) (S105-2), a target value LKFS (S105-3), and an LKFS error range (105-4), may calculate a control ratio (loudness control ratio) for adjusting an audio signal size (S105-5), and may calculate an LD control ratio (S105-6). Specifically, a weight factor (LD control ratio) for approaching the target LKFS may be computed using the LKFS of the input audio data calculated based on the input audio data, a Peek LKFS calculated by applying the Peek weighting value to the input audio data, and a received target LKFS.

$$new ratio = \frac{( Ori LKFS - peek LKFS )}{( Ori LKFS - Req LKFS )} \qquad [ Equation 6 ]$$

Furthermore, the audio signal size controller may perform normalization by adjusting the input audio signal size using the calculated control ratio (LD control ratio).

In accordance with the first embodiment of the present invention, an audio signal size may be controlled so that it complies with a standard with respect to a recorded and previously produced broadcasting program.

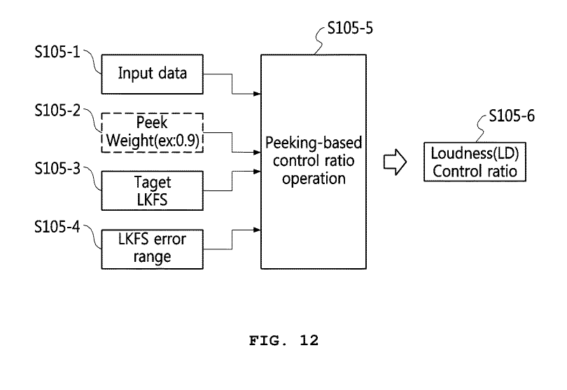

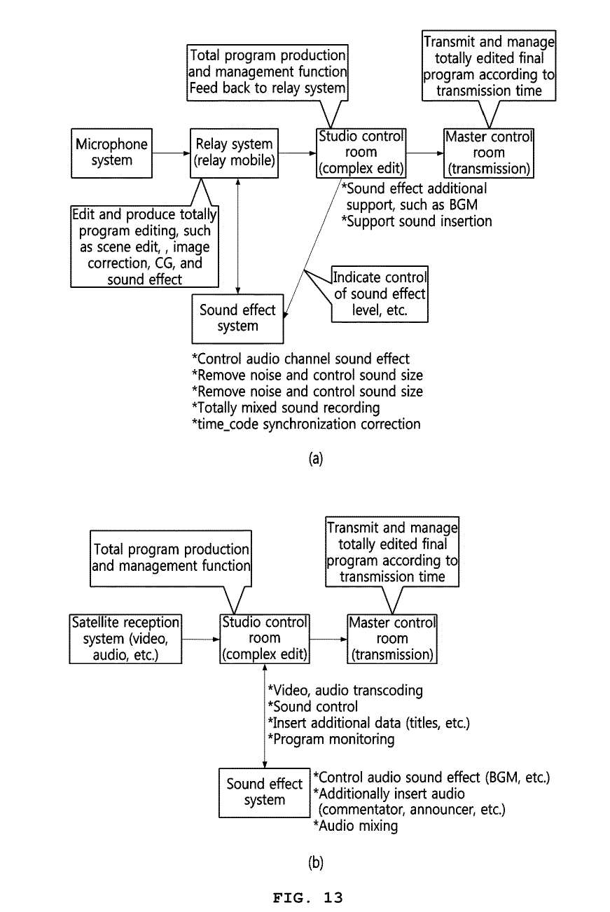

FIG. 13 is a diagram showing an example of the structure of a real-time broadcasting system.

Referring to FIG. 13, the live broadcasting system is quite different from a recording broadcasting system. A relay system does not include an Ingest server and does not use a part-based edit system separately. Instead, in the live broadcasting system, the relay system integrates such functions and performs the functions.

The relay system performs tasks, such as video/audio edit and effects, and controls an audio sound that is broadcasted live through a mutual instruction with a studio control room (complex edit room) which manages the production of the entire program.

The coordinated broadcasting program is transmitted by a master control room. Furthermore, a task for an audio sound and additional tasks, such as the insertion of titles, are performed on data that is broadcasted live and received through satellites in the studio control room (complex edit room). The resulting data is transmitted through the master control room. Accordingly, more variables are present in order to accurately control the audio volume of live broadcasting.

FIG. 14 is a diagram showing a second embodiment.

Referring to FIG. 14, in a live environment, as described above, a signal obtained through a microphone and a signal received through a satellite (hereinafter a live broadcasting signal) may be taken into consideration. A demultiplexer may demux the live broadcasting signal and select audio data (S201). Furthermore, an audio decoder may decode the selected audio data (S203).

Furthermore, an audio signal size controller may perform the normalization of an audio signal size using the decoded audio data (S206). Specifically, the audio signal size controller may analyze the audio signal size of the live audio data, may control a live audio signal size, and may perform the normalization. In this case, the audio signal size controller may perform the normalization using an audio signal size control value manually received from a user (S205).

Furthermore, an audio encoder may encode the audio data on which the normalization has been performed (S207). Furthermore, a multiplexer may multiplex the encoded audio data with other data not selected by the demultiplexer (S208).

Meanwhile, when the aforementioned data processing is performed, the data may be provided to a transmission room (S209).

In this case, a detailed operation of the audio signal size controller is described in detail with reference to FIG. 15.

Meanwhile, dotted blocks shown in the figure, for example, step S201, step S203, step S205, step S207, and step S208 may be omitted according to circumstances depending on the format of audio data. For example, if an input file is audio raw data, audio decoding is not required. If an audio raw file is required as output, the audio encoding module is not required. When a signal is streamed and transmitted, the audio signal size control system demuxs a file, decodes audio data into an audio signal if the audio data is a compression bit stream, and bypasses an audio decoding block if the audio data is raw data. The audio raw signal automatically controls a live audio signal according to an audio signal size criterion. The controlled signal is subjected to audio encoding and file formatting, if necessary, and broadcasted through a transmission device. Alternatively, an audio raw file may be output according to a request in output.

FIG. 15 is a detailed diagram illustrating the second embodiment. In describing FIG. 15 hereinafter, a detailed description of the parts described with reference to FIG. 14 is omitted, and the remaining parts are described.

Referring to FIG. 15, unlike in an existing system, a proposed system may have three types of mode in relation to the normalization of an audio signal size (S206). The first type is manual loudness control mode, the second type is half automatic loudness control mode, and the third type is automatic loudness control mode. The three types of mode can independently operate, each piece of mode may switch to another mode in the middle, and a difference between two types of mode according to mode switching may be compensated for by control of a mode change.

Manual loudness control mode may be mode in which a person (e.g., an audio signal editor) manually selects a weighting value for adjusting an audio signal size (e.g., using various buttons included in an audio signal processing device) and matches up the audio signal size with a target audio signal size by scaling an input audio signal using the selected weighting value. Half automatic loudness control mode is the same as manual loudness control mode in that a person manually selects a weighting value for control, but is different from manual loudness control mode in that it provides the aforementioned information so that a person uses information (e.g., a weighting value for scaling an audio signal size and an input audio signal size) for control of the audio signal size. Automatic loudness control mode may be mode in which an audio signal size is automatically controlled so that it is matched up with a target audio signal size without manual control of a person. In this case, switching between the pieces of mode may be performed through a half automatic loudness control mode selection button, a manual loudness control mode selection button, and an automatic loudness control mode selection button provided in the audio signal processing device. Alternatively, the audio signal processing device may include a single mode switching button for switching loudness control mode. When the mode switching button is selected, the pieces of mode may be sequentially switched.

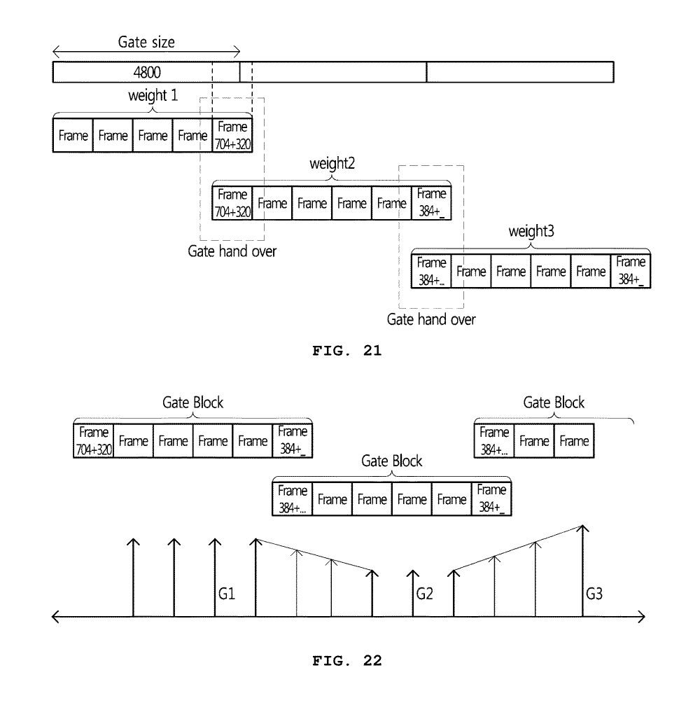

Meanwhile, a difference between two pieces of mode according to mode switching may be compensated for by control of a mode change. For example, if half automatic loudness control mode changes to automatic loudness control mode, a Peek weighting value may be changed. Alternatively, the interpolation of a gate weighting value described with reference to FIGS. 22 and 23 may be required. In this case, control of a mode change may include performing an operation for compensating for such a change.

Furthermore, in FIG. 15, a weighting value required to be matched up with a target audio signal size (target LKFS) with respect to a real-time input audio signal may be calculated through the aforementioned Peeking method.

In accordance with a second embodiment of the present invention, an audio signal size may be controlled with respect to a real-time/live-obtained broadcasting program so that it complies with a standard.

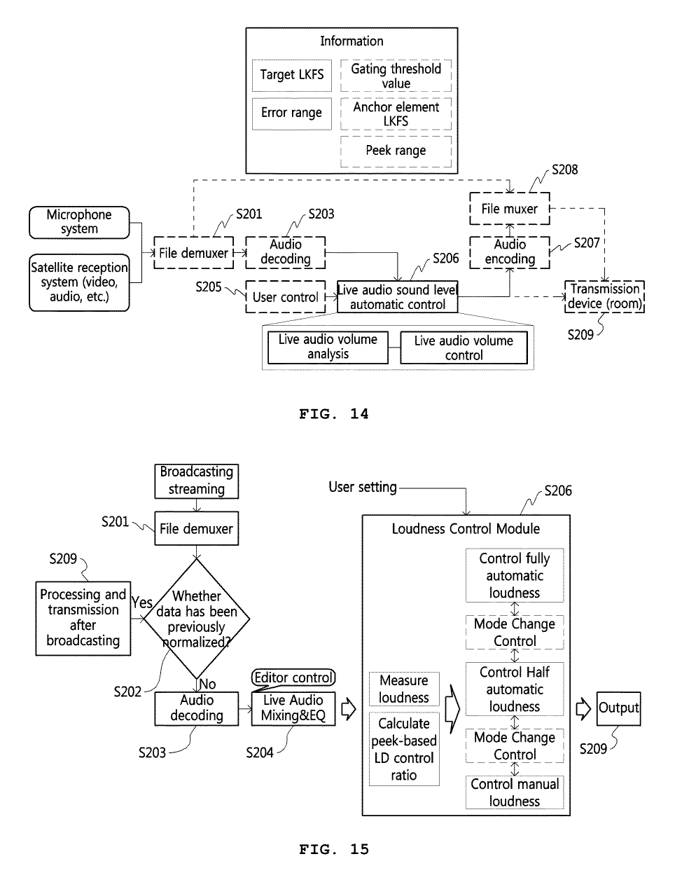

FIG. 16 is a diagram illustrating a method in which a live LD control step has been added to the last stage of the first embodiment, the second embodiment. Referring to FIG. 16, a live LD control step may be further added to the final stage of the method according to the first embodiment or second embodiment of the present invention.

That is, as described above, a file/local broadcasting program may be stored in the storage device (S103) through local LD control (S105) and used to be transmitted. Furthermore, as described above, the live broadcasting program may be processed in real time and transmitted through live LD control (S206).

In this case, from a viewpoint of a broadcasting station, in preparation for regulations, live LD control (S210) may be further performed on the final stage. That is, from a viewpoint of a broadcasting station, although a broadcasting program erroneously inputted in a previous stage is delivered, live LD control (S210) may be further placed so that the broadcasting program is filtered. In this case, the live LD control (S210) may include manual loudness control mode, half automatic loudness control mode, or automatic loudness control mode. In this case, preferably, automatic loudness control mode may be used so that 24-hour processing is automatically possible.

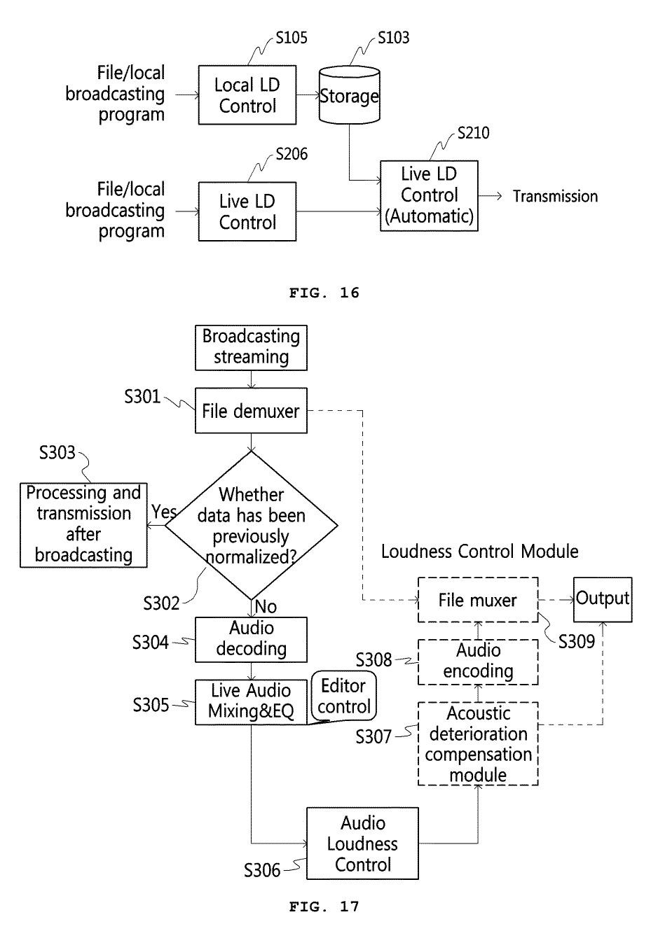

FIG. 17 is a diagram showing a third embodiment of a method of compensating for the deterioration of sound quality attributable to the adjustment of the audio signal size.

A method of adjusting an audio signal size may be variously performed depending on the conditions of input data as described above. In this case, if an audio signal size is matched up with a target LKFS and an error range, the construction of the audio signal may feel strong.

This is an adverse effect attributable to the normalization of an audio signal size. In this case, power of influence of audio normalization and user satisfaction which need to solve adverse effects attributable to the normalization while achieving the normalization of the audio signal size can be improved.

Accordingly, in accordance with the third embodiment of the present invention, a hearing deterioration compensation module for compensating for the aforementioned adverse effect may be further included. That is, referring to FIG. 17, the demultiplexer may demux existing recorded broadcasting program data or live broadcasting program data and select audio data (S301).

Furthermore, the normalization determination unit may determine whether the audio data has been previously normalized (S302).

If normalization has been previously performed on the audio data (S302: Y), subsequent procedures on the audio data on which the normalization has been performed may be performed (S303).

If normalization has not been previously performed on the audio data (S302: N), the audio decoder may decode the audio data (S304). Furthermore, editor control, such as Live Audi Mixing & EQ, may be performed (S305). Furthermore, the audio signal size controller may perform the normalization of an audio signal size using the decoded audio data (S306).

Furthermore, the hearing deterioration compensation module may compensate for an adverse effect attributable to the normalization performed by the audio signal size controller (S307). Furthermore, the audio encoder may encode the audio data on which acoustic deterioration compensation has been performed (S308).

Furthermore, the multiplexer may multiplex the encoded audio data with other data not selected by the demultiplexer (S309).

Meanwhile, dotted blocks shown in FIG. 17, for example, step S301, step S304, step S308, and step S309 may be omitted according to circumstances depending on the format of audio data. For example, steps S304 and S308 may be omitted depending on whether the audio data has been compressed.

In accordance with the third embodiment of the present invention, an audio signal size can be controlled while minimizing the deterioration of hearing audio sound quality attributable to the normalization of the audio signal size.

Meanwhile, the normalization of an audio signal size according to the aforementioned method may generate a significant change of a hearing environment for a digital broadcasting consumer. Furthermore, services/functions newly required for a digital broadcasting terminal may be generated because an audio signal size is normalized. That is, the digital broadcasting terminal may provide functions related to a broadcasting audio volume.

FIG. 18 is a diagram showing a fourth embodiment of a method of adjusting an audio signal size in a terminal. In describing FIG. 18 hereinafter, a detailed description of the part described with reference to FIG. 17 (i.e., the processing part (S301˜S3010) related to the transmission of a normalized audio signal) is omitted, and the remaining parts are described.

Referring to FIG. 18, the terminal may receive a normalized audio signal (S401), may process the received audio signal (S402), and may output the processed signal (S403). In this case, the audio signal process sing (S402) may be controlled for a user-tailored type, for example. That is, in digital broadcasting, information about broadcasting is provided to a user, and the use information of the user is accumulated when the user continues to use the terminal. The user information is analyzed based on such information, and a tailored audio sound service can be provided to the user. Furthermore, a broadcasting information-based user acoustic service can be directly applied based on user setting information.

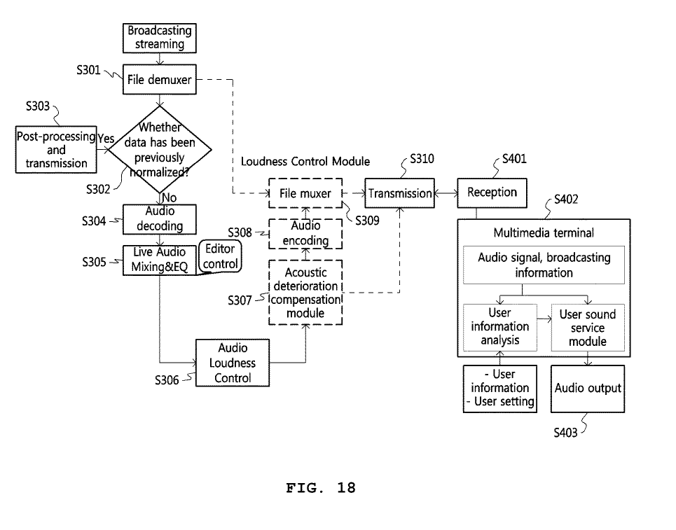

FIG. 19 is a detailed flowchart illustrating a method of adjusting an audio signal size in the apparatus for adjusting an audio signal size in accordance with a first embodiment of the present invention. Referring to FIG. 19, first, an audio signal may be received (S501). In this case, the input audio signal may be an audio signal according to operations (omissible operations), such as the demuxing and decoding shown in FIGS. 10 to 12, for example. The audio signal may have various waveforms and may be an audio signal having a waveform of a type (i.e., prior to normalization) shown in the front stage of FIG. 5, for example.

In this case, the audio signal size measurement unit may measure the LKFS of the input audio signal (original LKFS) using the method of measuring an audio signal size described with reference to FIGS. 6 to 8 (S503).

Furthermore, the audio signal size measurement unit may measure an initial Peek LKFS (S502). In this case, the initial Peek LKFS may be measured by scaling the input audio signal using a preset initial Peek weighting value and measuring the LKFS based on the scaled audio signal.

In this case, the preset initial Peek weighting value may be provided to a broadcasting signal, including an audio signal and a video signal, in the form of control information. Alternatively, the preset initial Peek weighting value may be provided as a value previously stored when the apparatus for adjusting an audio signal size was designed. Alternatively, the preset initial Peek weighting value may be provided as input from a user.

Meanwhile, the weighting value calculation unit may calculated (S506) an audio signal size (loudness) control ratio using first (S505: Y), a target value LKFS (S504), a measured initial Peek LKFS (S502), and the LKFS of a measured input audio signal (original LKFS) (S503). Specifically, the weighting value calculation unit may calculate the audio signal size (loudness) control ratio using Equation 7 below

diff1=original LKFS−peek LKFS

diff2=original LKFS−Target LKFS [Equation 7]

In this case, the audio signal size (loudness) control ratio may be diff1/diff2.

Furthermore, the weighting value calculation unit may calculate a new Peek weighting value by applying the calculated audio signal size (loudness) control ratio to Equation 8 below (S507).

if diff1<diff2

new weight=0.9^{diff1/diff2}

else

new weight=1.1^{diff1/diff2}

new_Peek_weight=previous_Peek_weight×new_weight [Equation 8]

In this case, a new_Peek_weighting value may mean a new Peek weighting value, a previous_Peek_weighting value may mean a Peek weighting value used prior to the calculation of the new_Peek_weighting value, and a new_weighting value may mean a weighting value calculated in Equation 8. For example, in accordance with Equations 7 and 8, in the first (S505: Y), the new Peek weighting value may be calculated by multiplexing the initial Peek weighting value and the new weighting value.

Meanwhile, in accordance with Equation 8, if a difference between the original LKFS and a Peek LKFS is smaller than that between the original LKFS and a target LKFS, a new Peek weighting value may be calculated by reducing a previous Peek weighting value. If the difference between the original LKFS and the Peek LKFS is equal to or greater than that between the original LKFS and the target LKFS, the new Peek weighting value may be calculated by increasing a previous Peek weighting value.

In Equation 8, 0.9 has been used as the weighting value for reducing the previous Peek weighting value, and 1.1 has been used as the weighting value for increasing the previous Peek weighting value. However, the present invention is not limited to such weighting values, and various weighting values may be used. For example, for finer control of the audio signal size, 0.99 may be used as the weighting value for reducing the previous Peek weighting value, and 1.01 may be used as the weighting value for increasing the previous Peek weighting value.

Meanwhile, in this case, the target value LKFS may be different depending on a target value LKFS determined by global countries according to their regulations and standards. For example, as shown in the latter part of FIG. 5 (i.e., after the normalization), the target value LKFS may be a 24 LKFS. Such a target value LKFS may be provided to a broadcasting signal, including an audio signal and a video signal, in the form of control information. Alternatively, the target value LKFS may be provided to a broadcasting signal, including an audio signal and a video signal, as a value previously stored when the apparatus for adjusting an audio signal size was designed. Alternatively, the target value LKFS may be provided as input from a user.

Meanwhile, the audio signal size control unit may control the audio signal size using the new Peek weighting value calculated through the aforementioned operation. Specifically, the audio signal size control unit may control the audio signal size by scaling the input audio signal (S501) using the calculated new Peek weighting value (S508).

Furthermore, the audio signal size measurement unit may measure the LKFS of an audio signal (new Peek LKFS) (S508) whose audio signal size has been controlled based on the new Peek weighting value (S509).

Meanwhile, the audio signal size control unit may calculate an LKFS error (S511) by comparing the target value LKFS (S504) with the measured new Peek LKFS (S509).

Furthermore, the audio signal size control unit may compare the LKFS error D with a predetermined error range T (S512). For example, if the target value LKFS and the audio signal size error range are 24 LKFS (target LKFS)+/−2 dB (error range), whether a difference between the target value LKFS and the new Peek LKFS is greater or equal to an error range may be determined. Such a predetermined error range (LKFS error range) (S510) may be provided to a broadcasting signal, including an audio signal and a video signal, in the form of control information. Alternatively, the predetermined error range may be provided as a value previously stored when the apparatus for adjusting an audio signal size was designed. Alternatively, the predetermined error range may be provided as input from a user.

If the LKFS error D is smaller than the predetermined error range T (S513: Y), the audio signal size control unit may output an audio signal whose audio signal size has been controlled based on the new Peek weighting value.

If the LKFS error D is not smaller than the predetermined error range T (S513: N), the audio signal size control unit may perform control so that the aforementioned control operation is repeated. In this case, if the aforementioned control operation is repeated, the weighting value calculation unit is not the first (S505: N) and may calculate a new audio signal size (loudness) control ratio (S506) using the target value LKFS (S504), the measured new Peek LKFS (S509), and the measured original LKFS (S503). In this case, the weighting value calculation unit may calculate the loudness control ratio using Equation 7. Furthermore, the weighting value calculation unit may calculate the new Peek weighting value by applying the calculated audio signal size (loudness) control ratio to Equation 8 (S507). That is, the aforementioned operation may be repeated until the audio signal size satisfies the target value LKFS and the error range.

Meanwhile, the input audio signal (S501) in accordance with the first embodiment of the present invention is the audio signal of a previously produced broadcasting program and may be an audio signal from the start and end of the broadcasting program. Accordingly, in accordance with the first embodiment of the present invention, the audio signal size may be controlled based on the audio signal size of an audio signal (original LKFS) from the start and end of the broadcasting program.

Meanwhile, the encoding operation and the multiplexing operation (omissible) shown in FIGS. 10 to 12 may be performed on the output audio signal (S513).

The apparatus or method for adjusting an audio signal size or method in accordance with the first embodiment of the present invention may be included in and performed on the producer side for producing an audio signal or the supplier side for supplying the produced audio signal. Alternatively, the apparatus or method for adjusting an audio signal size in accordance with the first embodiment of the present invention may be included in or performed on the user side (e.g., a portable multimedia device, such as an MP3 player) for receiving and outputting an audio signal.

In accordance with the first embodiment of the present invention, an audio signal size may be automatically controlled with respect to a recorded and previously produced broadcasting program.

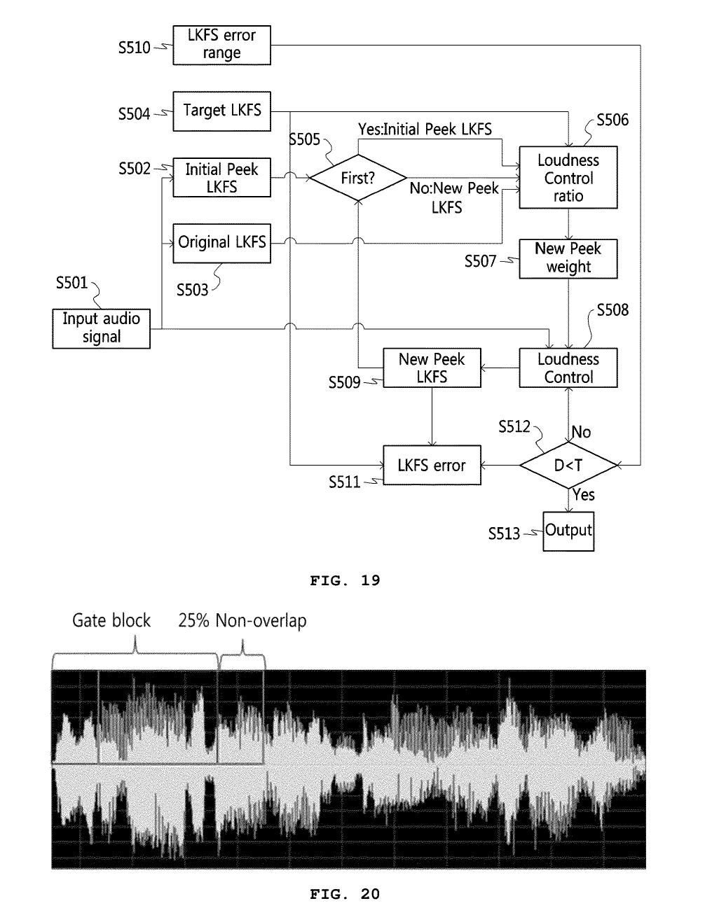

FIG. 20 is a diagram illustrating a method of measuring an audio signal size to which the audio gating method described in ITU-R 1770-2 has been added. In this case, as shown in FIG. 20, the audio gating method may include measuring the LKFS of a gate block 1, measuring the LKFS of a gate block 2 using the overlap and shift method, measuring an LKFS for each gate block by repeating the overlap and shift method, performing bundle processing if the LKFS of the measured gate block is less than a threshold LKFS (−70 LKFS in the ITU-R 1770-2), and performing audio signal size measurement on an audio signal to which gating has been applied.

In this case, with respect to the aforementioned gate block, in the ITU-R 1770-2, the gate block has a gate size of 0.4 s and has a structure overlapped by 75%.

Meanwhile, in a real-time/live environment, an audio signal is obtained for each gate block. The LKFS of each gate block is measured using Equation 4 to 5. A new Peek weighting value for adjusting an audio signal size for each gate block may be calculated using the aforementioned method of FIG. 19. In this case, if the audio signal size is controlled for each gate block using the new Peek weighting value calculated for each gate block, a discontinuous sound may be generated due to a difference in the weighting value between neighboring gate blocks.

In order to solve such a problem, the method of adjusting an audio signal size n accordance with the fifth embodiment of the present invention may perform the following processing.

FIG. 21 is a diagram illustrating gate handover in order to describe a method of adjusting an audio signal size in accordance with a fifth embodiment of the present invention. Referring to FIG. 21, the gate size of a region which is not overlapped with a gate block may be 4800 samples, for example. Furthermore, if a codec, such as AAC or AC-3, is used, a single frame size that determines one data size may be 1024 samples. In this case, gate handover in which a single frame overlaps with two gate blocks may be generated.

FIG. 22 is a diagram illustrating a method of adjusting an audio signal size in accordance with the fifth embodiment of the present invention. Referring to FIG. 22, the method of adjusting an audio signal size in accordance with the fifth embodiment of the present invention may include adjusting an audio signal size by interpolating a gate weighting value from a frame in which gate handover is generated. In this case, the gate weighting value may be a new Peek weighting value calculated using the aforementioned method of FIG. 19 with respect to each gate block.

In accordance with the fifth embodiment of the present invention, gate delay attributable to the interpolation of a gate weighting value is not generated. That is, at a point of time at which data is received in a frame in which gate handover is generated, the gate weighting values of two gate blocks overlapping across the frame in which gate handover is generated can be previously calculated. Accordingly, a gate weighting value can be interpolated without delay from the frame in which gate handover is generated using the gate weighting values of the two gate blocks.

Meanwhile, in accordance with the fifth embodiment of the present invention, various interpolation methods may be used in order to interpolate a gate weighting value. For example, the present linear interpolation method may be used. The present linear interpolation method is described in detail with reference to FIG. 23.

FIG. 23 is a diagram illustrating linear interpolation, that is, an example of interpolation in accordance with a fifth embodiment of the present invention. Referring to FIG. 23, linear interpolation, such as Equation below, may be used.

$${W}_{i} = {W}_{G 1} + \frac{{W}_{G 1} - {W}_{G 2}}{InterFrame} \times i , \\ i = 1 InterFrame - 1 \qquad [ Equation 9 ]$$

In Equation 9, W_{G1} is the gate weighting value of a gate block 1, W_{G2} is the gate weighting value of a gate block 2, i is the number of gate weighting values to be interpolated, and an interframe is the number of frames from an interpolation start frame to an interpolation end frame.

For example, if Equation 9 is applied using the number of interframes of 3, as shown in FIG. 22, a gate weighting value to be applied to two frames (weighting values W₁ and W₂ indicated by a red color) may be calculated. That is, the number of interpolated gate weighting values may be variably controlled by selectively controlling the number of interframes.

Meanwhile, in accordance with the fifth embodiment of the present invention, the gate weighting value interpolation method may be applied to all methods for adjusting an audio signal size using a gate weighting value. For example, the gate weighting value interpolation method may be applied to a previously recorded broadcasting program and may control an audio signal size and may be applied to a live broadcasting program and may control an audio signal size.

Furthermore, the apparatus or method for adjusting an audio signal size in accordance with the fifth embodiment of the present invention may be included in or performed on the producer side for producing an audio signal or the supplier side for supplying the produced audio signal. Alternatively, the apparatus or method for adjusting an audio signal size in accordance with the fifth embodiment of the present invention may be included in and performed on the user side (e.g., a portable multimedia device, such as an MP3 player) for receiving and outputting an audio signal.

In accordance with the fifth embodiment of the present invention, gate delay attributable to the interpolation of a gate weighting value may not be generated by interpolating a gate weighting value from a frame in which gate handover is generated.

Furthermore, the number of interpolated gate weighting values may be variably controlled.

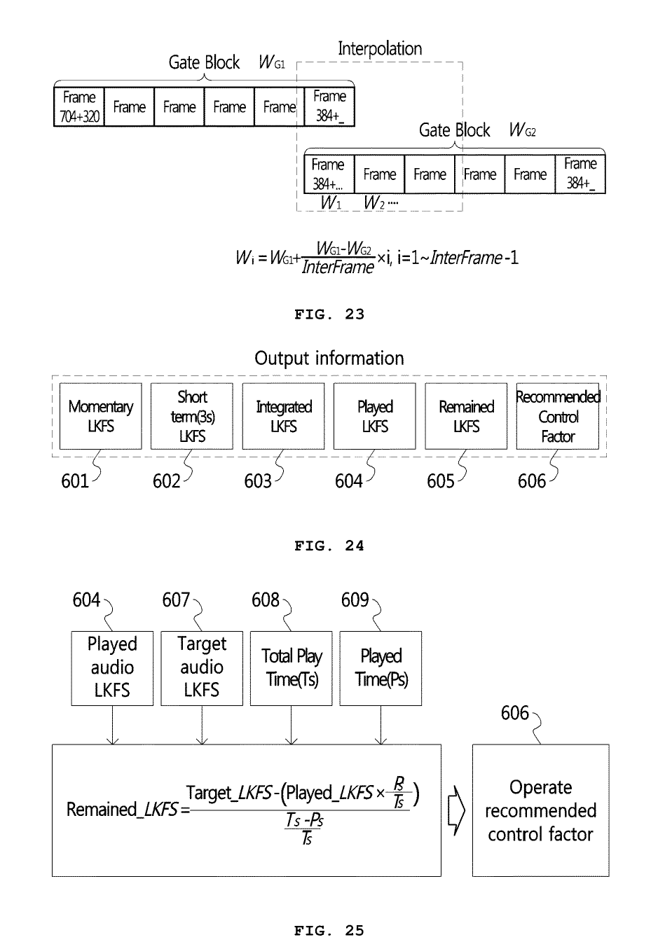

FIG. 24 is a diagram showing an example of information provided in half automatic loudness control mode of the second embodiment of the present invention. In this case, half automatic loudness control mode is the same as manual loudness control mode in that a person manually selects a weighting value for control, but may be different from manual loudness control mode in that it provides the aforementioned information so that a person may use information for control of an audio signal size.

In such half automatic loudness control mode, information for adjusting an audio signal size, as shown in FIG. 24, at least one of a momentary LKFS 601, a short term (3 s) LKFS 602, an integrated LKFS 603, a played LKFS 604, the remained LKFS 605, and the recommended control factor 606 may be included.

In this case, the momentary LKFS 601 may be a weighting value for adjusting a calculated audio signal size using the LKFS of an input audio signal (e.g., the LKFS of the input audio signal for 0.4 S as in FIG. 20) with respect to a gate block. In the short term (3 s), the LKFS 602 may be a weighting value for adjusting a calculated audio signal size using the LKFS of an input audio signal for 3 S with respect to a gate block. The integrated LKFS 603 may be a weighting value for adjusting a calculated audio signal size using the LKFS of an input audio signal so far with respect to a gate block. The played LKFS 604 may be a weighting value for adjusting a calculated audio signal size using the LKFS of an input audio signal output so far with respect to a gate block. The remained LKFS 605 may be a weighting value for adjusting an audio signal size calculated using an insufficient or exceeded LKFS of the played LKFS 604 versus a target value LKFS with respect to a gate block. The recommended control factor 606 may be a weighting value for adjusting an audio signal size calculated using the remained LKFS 605 with respect to a gate block.

The momentary LKFS 601, the short term (3 s) LKFS 602, and the integrated LKFS 603 may be measured using Equation 4 to 5.

Meanwhile, the played LKFS 604 may be different from the integrated LKFS 603, that is, the LKFS of an input audio signal whose audio signal size has not been controlled, in that an output audio signal (i.e., the audio signal size may be controlled by the aforementioned operations of FIGS. 22 and 23 and output to an audio playback device) is an audio signal whose audio signal size has been controlled.

The played LKFS 604 may be calculated using Equation 10 below.

$$[ Equation 10 ]$$

$$x \text{:} filtered signal by low filters$$

$$pSum = {\sum }_{i}^{M} \sqrt{{x}_{i}^{2}}$$

$$pMean = \frac{1}{M} {\sum }_{i}^{M} \sqrt{{x}_{i}^{2}}$$

$$played\_mean = \frac{previous\_Mean \times ( N - 1 ) + pMean}{N}$$

$$PlayedLKFS = - 0.691 \times 10 \times {log}_{10} ( played mean )$$

In this case, x is an audio signal output so far with respect to a signal that has passed through the two filters defined in the LKFS measurement algorithm. M is the number of samples of a gate block. N is the number of gate blocks to which an audio signal has been inputted so far.

That is, referring to FIG. 20, in a real-time/live environment, since an audio signal is inputted to each gate block, as in Equation 10, the mean played_mean of output audio signals so far needs to be calculated. Accordingly, when the mean played_mean is obtained, the played LKFS 604 may be measured by applying the equation described the ITU-R 1770-2.

Meanwhile, when calculation is performed as in Equation 10, if the data of an audio signal is increased, an N value becomes very high. In the case of a fixed-point processor, a result of the multiplication of previous_Mean and N−1 may exceed a processor range. Furthermore, there may be a significant even in a floating point processor. It may be a burden on the processing of the processor and the storage capacity of memory.

In order to supplement such a problem, in accordance with an embodiment of the present invention, as in Equation 11 below, the mean present_mean of output audio signals so far may be calculated using a method of dividing N not a method of multiplying N. In this case, the played LKFS 604 may be measured by applying the calculated present_mean to the mean played_mean of Equation 10. In this case, a burden on the processing of the processor and the storage capacity of memory can be reduced.

$$[ Equation 11 ]$$

$$if previous Mean > pMean$$

$$present\_Mean = previous\_Mean - \vert \frac{previous\_Mean - pMean}{N} \vert$$

$$else$$

$$present\_Mean = previous\_Mean - \vert \frac{previous\_Mean - pMean}{N} \vert$$

FIG. 25 is a diagram showing a method of calculating a recommended control factor that belongs to information provided in half automatic loudness control mode of the second embodiment of the present invention. Referring to FIG. 25, the remained LKFS 605 may be calculated using Equation 12 below, and the recommended control factor 606 may be calculated using the measured remained LKFS 605.

$$Remained\_LKFS = \frac{Taget\_LKFS - ( Played\_LKFS \times \frac{{P}_{s}}{{T}_{s}} )}{\frac{{T}_{s} - {P}_{s}}{{T}_{s}}} \qquad [ Equation 12 ]$$

In this case, the remained LKFS 605 may be calculated using the played LKFS 604, the target LKFS 607, a total time of an audio signal (total play time (Ts)) 608, and the current time of the output audio signal (played time (Ps)) 609. Referring to Equation 12, the remained LKFS 605 may means an insufficient or exceeded LKFS of the played LKFS 604 compared to a target value LKFS.

The recommended control factor 606 may be a weighting value for adjusting an audio signal size using the remained LKFS 605. That is, the remained LKFS 605 means an insufficient or exceeded LKFS of the played LKFS 604 compared to the target value LKFS 607. The weighting value calculation unit may calculate a weighting value at which a total audio signal size of an audio signal to be output becomes the target value LKFS 607 using the remained LKFS 605.

Meanwhile, in half automatic loudness control mode, such as the aforementioned momentary LKFS 601, short term (3 s) LKFS 602, integrated LKFS 603, played LKFS 604, remained LKFS 605, and recommended control factor 606, information for adjusting an audio signal size may be provided through a display screen included in the apparatus for adjusting an audio signal size.

In accordance with an embodiment of the present invention, a user can control an audio signal size more easily in a real-time/live environment because information for adjusting an audio signal size is provided.

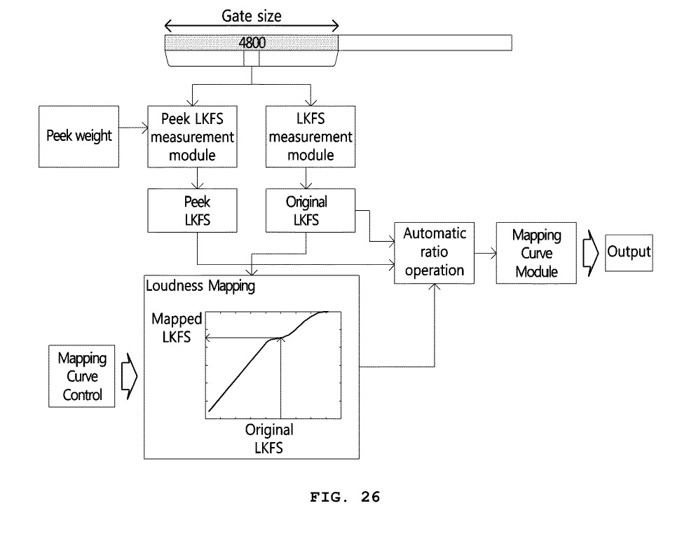

FIG. 26 is a diagram showing a method of adjusting an audio signal size in automatic loudness control mode of the second embodiment of the present invention. In this case, automatic loudness control mode may be mode in which an audio signal size is automatically matched up with a target audio signal size without manual control of a person. In automatic loudness control mode, a gate weighting value to be applied for each gate block needs to be automatically calculated.

To this end, in accordance with an embodiment of the present invention, in automatic loudness control mode, the weighting value calculation unit may automatically calculate a gate weighting value for scaling an audio signal for each gate using an input audio signal size (original LKFS) obtained for each gate block in real time, an audio signal size (Peek LKFS) obtained by scaling the input audio signal obtained for each gate block in real time using a Peek weighting value, and a mapped LKFS calculated by applying an input audio signal size (original LKFS) to a mapping curve. The audio signal size control unit may control an audio signal size using the calculated gate weighting value.

In this case, the mapping curve may be a curve in which an overall size deviation of an output audio signal is maintained while making a total audio signal size of the audio signal inputted from the start and end of the audio signal a target audio signal size value (target LKFS) (e.g., −24 LKFS). That is, if a normalization task for making the total audio signal size of the input audio signal a target audio signal size value (e.g., −24 LKFS) is performed, a block having a small audio signal size for each gate block is increased, and a block having a large audio signal size for each gate block is decreased. In this case, there may be a problem in that a deviation of a sound size delivered to a person's ear is reduced. Accordingly, in accordance with an embodiment of the present invention, a deviation of a sound size delivered to a person's ear can be maintained using the mapping curve that maintains an overall size deviation of an audio signal.

Meanwhile, the weighting value calculation unit may calculate diff1/diff2, that is, an audio signal size (loudness) control ratio by applying the mapped LKFS to the target LKFS of Equation 7 and may calculate a new gate weighting value by applying the calculated audio signal size (loudness) control ratio to Equation 8.

Furthermore, the audio signal size control unit may control an audio signal size using a gate weighting value for scaling an audio signal calculated for each gate block. A detailed description of such an operation has been described in detail with reference to FIG. 19 and thus omitted.

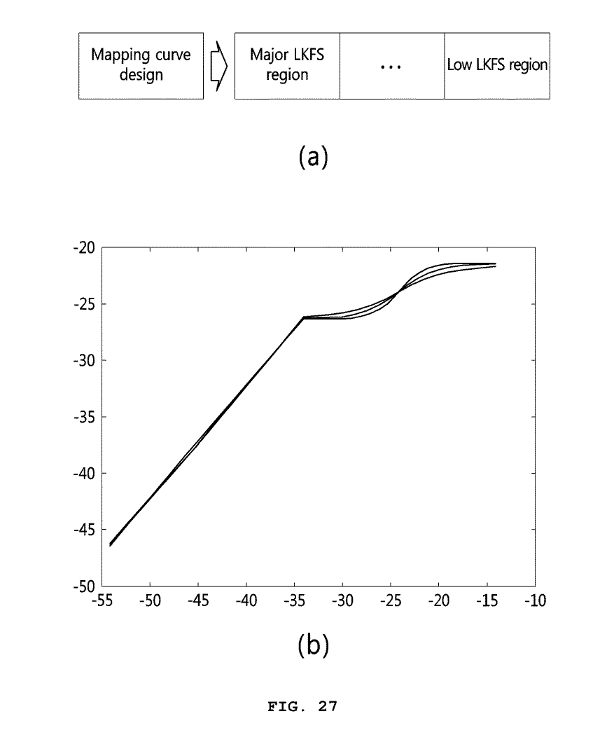

FIG. 27 is a diagram showing a method of designing a mapping curve for calculating a mapping audio signal size (mapped LKFS) according to FIG. 26. In this case, a mapping curve is a curve indicative of the relationship between an input audio signal size (original LKFS) and a mapping audio signal size (mapped LKFS) for each gate block. Referring to FIG. 27(a), the mapping curve may be designed by separating a major LKFS region and a non-major LKFS region (low LKFS region).

In this case, the non-major LKFS region (low LKFS region) may be an LKFS region in which an input audio signal size delivered to a person's ear is smaller than a predetermined value. The major LKFS region may be an LKFS region in which an input audio signal size delivered to a person's ear is equal to or greater than the predetermined value.

That is, referring to FIG. 27 (b), the major LKFS region may design a mapping curve based on a variable weighting value, and the non-major LKFS region may design a mapping curve in a linear form.

In this case, the mapping curve for the major LKFS region may be designed using Equation 13 below.

$${oLKFS}_{i} = \frac{1}{( 1 + exp ( - {iLKFS}_{i} \times w ) )} \qquad [ Equation 13 ]$$

In this case, iLKFS is an input audio signal size (original LKFS) for each gate, oLKFS is an audio signal size (mapped LKFS) mapped to each gate, and w is a weighting value. Accordingly, the variable mapping curve for the major LKFS region can be generated. The mapping curve may be controlled through control of the mapping curve.

In accordance with an embodiment of the present invention, an input audio signal is normalized using a mapping curve and output. Accordingly, the audio signal that is normalized and output can maintain a size deviation of the input audio signal, and thus a deviation of a sound size delivered to a person's ear can be maintained.

Meanwhile, if an input audio signal size is normalized into a target audio signal size (target LKFS) and an error range and output through the aforementioned operation, a feeling that the configuration of an output audio signal becomes flat may be strengthened. Such a part is an adverse effect attributable to the normalization of an audio signal size. Accordingly, power of influence of the normalization of an audio signal size and user satisfaction which need to solve the adverse effect attributable to the normalization of an audio signal size while achieving the normalization of an audio signal size can be improved.

Furthermore, audio mixing and EQ shown in S305 of FIG. 17 is a part controlled by an audio editor. An audio editor may edit/modify a broadcasting audio signal based on his or her feeling and artistry. Furthermore, when an edited/modified audio signal is directly transmitted to the audio signal size control module, the audio signal size control module may normalize an audio signal size into a target audio signal size (target LKFS) by reducing a part higher than the target audio signal size (target LKFS) and increasing a part lower than the target audio signal size (target LKFS) or generally adjusting the audio signal size. Furthermore, the audio signal size control module outputs an audio signal having a controlled audio signal size. In such a method, however, as normalization is performed, a volume deviation edited/modified by an audio editor may disappear or reduce.

Accordingly, in accordance with a third embodiment of the present invention, there are provided two methods in order to solve such a problem.

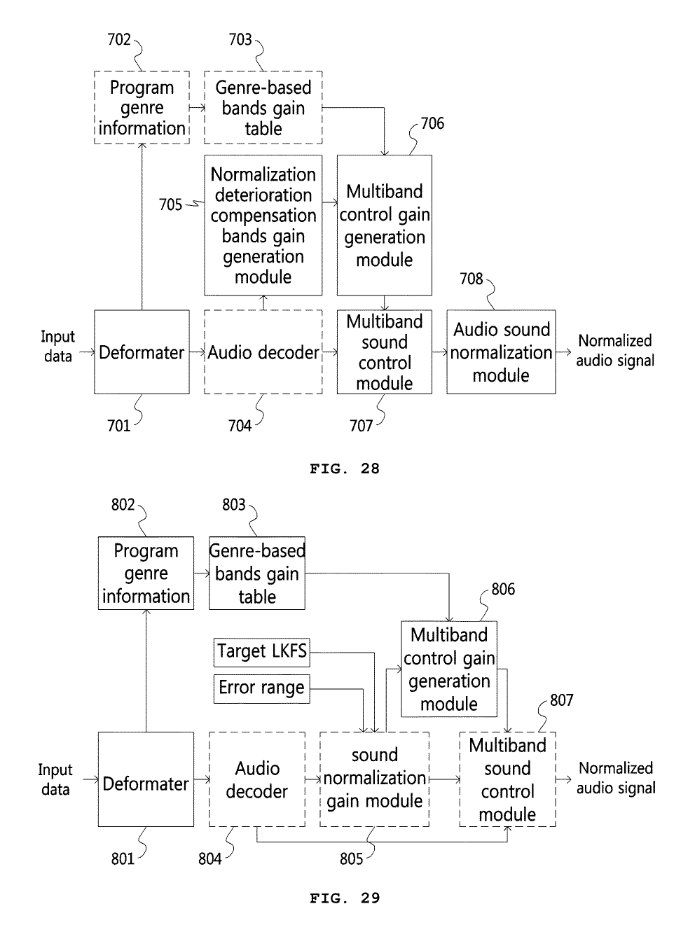

FIG. 28 is a detailed diagram showing one of methods of adjusting an audio signal size in accordance with a third embodiment of the present invention. Referring to FIG. 28, the one method may be a method for compensating for the deterioration of sound quality by taking into consideration the deterioration of sound quality which may occur due to the normalization of an audio signal size before the normalization of an audio signal size 708 is performed.

Specifically, when the data of a broadcasting signal (audio data, video data, and broadcasting data (including meta data regarding broadcasting, for example, program genre data)) is received, a deformatter 701 may separate program genre data 702 and audio data from the data of the input broadcasting signal. If the input data includes program genre data, the deformatter 701 may detect a band gain table that belongs to a previously stored genre-based band gain table 703 and that corresponds to separated program genre data. Furthermore, the deformatter 701 may send a band gain corresponding to the detected band gain table to a multi-band control gain generation module 706. In this case, if the input data does not include program genre data, the band gain table corresponding to the program genre data may not be taken into consideration.

Meanwhile, if the separated audio data is compressed data, it may be decoded through an audio decoder 704. Furthermore, a normalization deterioration compensation band gain generation module 705 may analyze the decoded audio data and determine the compensation gain of each band. In this case, the normalization deterioration compensation band gain generation module 705 may determine the compensation gain of each band through a predetermined table. Furthermore, the normalization deterioration compensation band gain generation module 705 may send the determined compensation gain to the multi-band control gain generation module 706. In this case, if the separated audio data is not compressed data, the audio decoding step may be omitted.

Meanwhile, the multi-band control gain generation module 706 may calculate the gain of a multi-band by fusing the compensation gain determined by the normalization deterioration compensation band gain generation module 705 and a gain according to a genre determined by the genre-based band gain table 703.

Furthermore, a multi-band volume control module 707 may convert the decoded audio data into a multi-band. Furthermore, the multi-band volume control module 707 may apply the multi-band gain, calculated by the audio multi-band control gain generation module 706, to the multi-band converted from the decoded audio data. Furthermore, the multi-band volume control module 707 may convert the applied multi-band into audio data again.

In this case, the converted audio data may be audio data in which deterioration attributable to normalization has been previously taken into consideration.

Meanwhile, the converted audio data may be normalized through the audio volume normalization module 708. In this case, the audio volume normalization module 708 may be a module for calculating the weighting value described in the first and the second embodiments of the present invention and performing an operation for normalizing an audio signal.

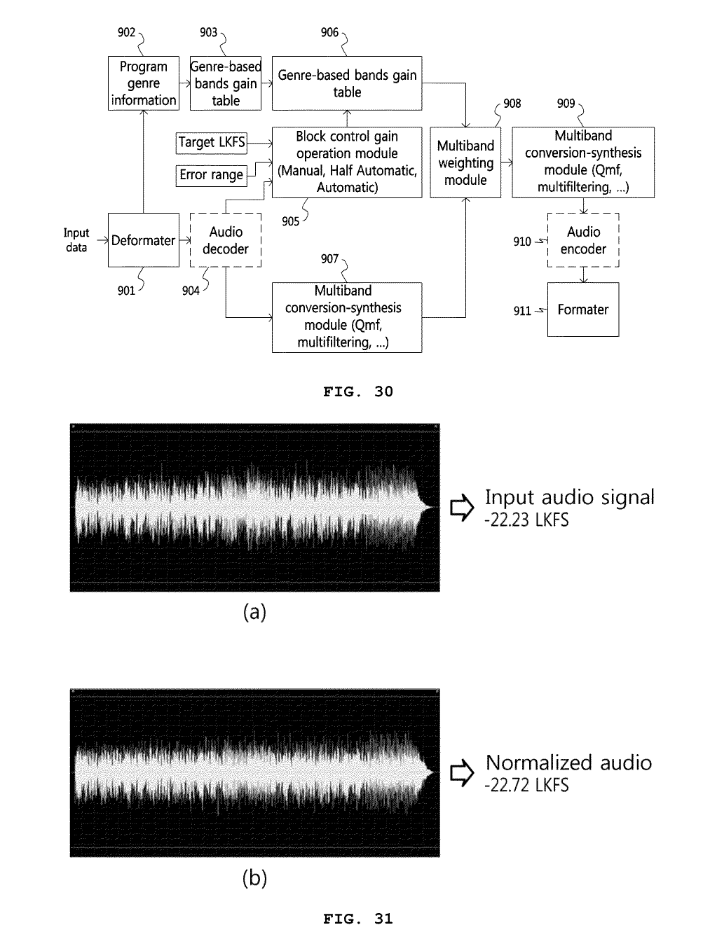

FIG. 29 is a detailed diagram showing the other of the methods of adjusting an audio signal size in accordance with the third embodiment of the present invention. FIG. 30 is a detailed diagram of FIG. 29. Referring to FIGS. 29 and 30. The other method may be a method for compensating for the deterioration of sound quality generated due to the normalization of an audio signal size after the normalization of the audio signal size is performed.

Specifically, when the data of a broadcasting signal (audio data, video data, and broadcasting data (including meta data regarding broadcasting, for example, program genre data)) is received, a deformatter 801 may separate program genre data 802 and audio data from the data of the input broadcasting signal. If the input data includes program genre data, the deformatter 801 may detect a band gain table that belongs to a previously stored genre-based band gain table 803 and that corresponds to the separated program genre data. Furthermore, the deformatter 801 may send a band gain, corresponding to the detected band gain table, to a multi-band control gain generation module 806. In this case, the genre-based band gain table may be a table including gain values for highlighting a voice region or highlighting a background region in response to the genre of an input broadcasting program. In this case, if the input data does not include program genre data, the band gain table corresponding to the program genre data may not be taken into consideration.

Meanwhile, if the separated audio data is compressed data, it may be decoded through an audio decoder 804. Furthermore, an audio volume normalization gain generation module 805 may calculate a gain for normalization using the decoded audio data. Furthermore, the audio volume normalization gain generation module 805 may send the calculated gain for normalization to a multi-band control gain generation module 807. In this case, the audio volume normalization gain generation module 805 may be a module for calculating the weighting value described in the first and the second embodiments of the present invention and performing an operation for normalizing an audio signal. In this case, if the separated audio data is not compressed data, the audio decoding step may be omitted.

Meanwhile, the multi-band control gain generation module 806 may calculate the gain of a multi-band by fusing the normalization gain calculated by the audio volume normalization gain generation module 805 and a gain according to a genre computed in the genre-based band gain table 803.

Furthermore, the multi-band volume control module 807 may convert the decoded audio data into a multi-band. Furthermore, the multi-band volume control module 807 may apply the multi-band gain, calculated by the multi-band control gain generation module 806, to the multi-band converted by the decoded audio data. Furthermore, the multi-band volume control module 807 may convert the applied multi-band into audio data again.

The operation of FIG. 29 is described in more detail with reference to FIG. 30. In this case, in describing FIG. 30, a detailed description of the operation described with reference to FIG. 29 is omitted.

Referring to FIG. 30, an audio volume normalization gain generation module 905 is a block for computing a gain for audio normalization, and may measure an input audio signal size and compute a gain value for complying with a target audio signal size (target LKFS). In this case, in the method of calculating a gain, a gain may be obtained through manual, half automatic, and automatic mode in a real-time/live environment.

Meanwhile, a multi-band control gain generation module 906 may calculate the gain of a multi-band by fusing the normalization gain calculated by the audio volume normalization gain generation module 905 and a gain according to a genre computed in a genre-based band gain table 903.

For example, the multi-band control gain generation module 906 may calculate the gain of a multi-band by applying [nGᵢ=g*Gᵢ, i=1˜the number of multi-bands] to the gain.

In this case, g may be a normalization gain calculated by the audio volume normalization gain generation module 905, Gᵢ may be a gain according to a genre computed in the genre-based band gain table 903, and nGᵢ may be the gain of a multi-band in which both normalization and a genre are taken into consideration.

Meanwhile, a multi-band conversion analysis module 907 may convert the decoded audio data into a multi-band signal using a scheme, such as QMF or multi-filtering. Furthermore, a multi-band weighting module 908 may apply the gain of the multi-band, calculated by the multi-band control gain generation module 906, to the converted multi-band signal. Furthermore, the multi-band signal to which the gain has been applied may be converted into audio data through the multi-band conversion synthesis module 909.

The apparatus or method for adjusting an audio signal size in accordance with the third embodiment of the present invention may be included in or performed on the producer side for producing an audio signal or on the supplier side for supplying the produced audio signal. Alternatively, the apparatus or method for adjusting an audio signal size in accordance with the third embodiment of the present invention may be included in or performed on the user side (e.g., a portable multimedia device, such as an MP3 player) for receiving and outputting an audio signal.

Meanwhile, in accordance with the method of compensating for hearing deterioration attributable to the normalization of the present invention, compensation filtering can be performed by taking into consideration that a person's hearing sense is sensitive to a low band and insensitive to a high band and that a deviation of an audio signal size is reduced due to normalization. Accordingly, adverse effects attributable to the normalization of an audio signal size, such as a problem in that the configuration of an audio signal becomes flat and a problem in that a volume deviation edited/modified by an audio editor disappears or reduces, in a normalized and output audio signal can be solved.

FIGS. 31 to 33 are diagrams showing a comparison between the waveform of an input audio signal and the waveform of a normalized audio signal.

FIG. 31(a) is a diagram showing the waveform of an input pop audio signal, and FIG. 31(b) is a diagram showing the waveform of a normalized pop audio signal. From FIG. 31, it may be seen that the input pop audio signal size was −22.23 LKFS, but the normalized pop audio signal size becomes −22.72 LKFS through the aforementioned normalization operation and thus the input pop audio signal size have been normalized within a target audio signal size and an error range.

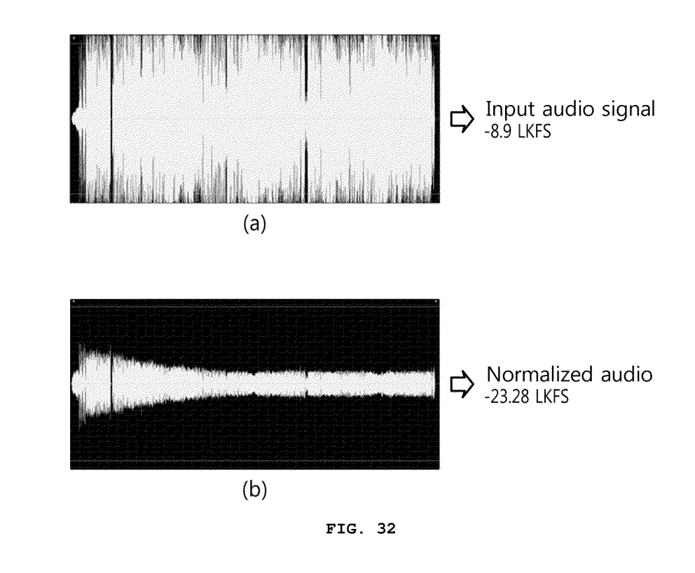

FIG. 32(a) is a diagram showing the waveform of an input K-pop audio signal, and FIG. 32(b) is a diagram showing the waveform of a K-pop normalized audio signal. From FIG. 32, it may be seen that the input K-pop audio signal size was −8.9 LKFS, but the normalized K-pop audio signal size becomes −23.28 LKFS through the aforementioned normalization operation and thus the input K-pop audio signal has been normalized within a target audio signal size and an error range.

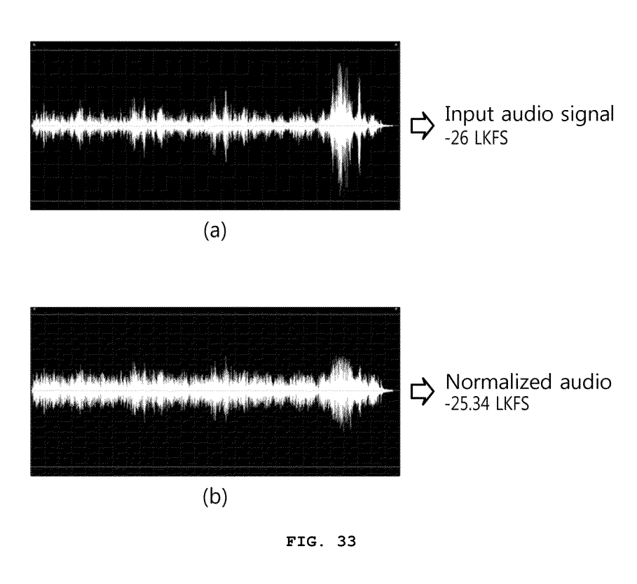

FIG. 33(a) is a diagram showing the waveform of an input classical audio signal, and FIG. 33(b) is a diagram showing the waveform of a normalized classical audio signal. From FIG. 33, it may be seen that the input classical audio signal size was −26 LKFS, but the normalized classical audio signal size becomes −25.34 LKFS through the aforementioned normalization operation and thus the input classical audio signal size has been normalized within a target audio signal size and an error range.

Meanwhile, the aforementioned methods according to various embodiments of the present invention may be produced in the form of a program that is to be executed by a computer and may be stored in a computer-readable recording medium. Multimedia data having a data structure according to the present invention may also be stored in computer-readable recording media. The computer-readable recording media include all types of storage devices in which data readable by a computer system is stored. The computer-readable recording media may include ROM, RAM, CD-ROM, a magnetic tape, a floppy disk, and an optical data storage device, for example. Furthermore, the computer-readable recording media includes media implemented in the form of carrier waves (e.g., transmission through the Internet).

Furthermore, the computer-readable recording medium may be distributed over computer systems connected over a network, and the processor-readable code may be stored and executed in a distributed manner. Furthermore, functional programs, code, and code segments for implementing the method may be easily reasoned by programmers in the art to which the present invention pertains.

Furthermore, although the preferred embodiments of the present invention have been illustrated and described above, the present invention is not limited to the aforementioned specific embodiments, and those skilled in the art to which the present invention pertains may modify the present invention in various ways without departing from the gist of the present invention written in the claims. Such modified embodiments should not be individually understood from the technical spirit or prospect of the present invention.

1. A method of adjusting an audio signal size, comprising steps of:
calculating a first band gain for compensating for normalization deterioration attributable to a normalization of a size of an input audio signal into a size of a target audio signal using the input audio signal;
applying the calculated first band gain to the input audio signal; and
normalizing an audio signal to which the calculated first band gain has been applied.

2. The method of claim 1, further comprising steps of:
receiving a broadcasting signal of a broadcasting program;
detecting program genre information in the received broadcasting signal; and
calculating a second band gain corresponding to the detected program genre information,
wherein the step of applying the calculated first band gain to the input audio signal comprises applying the calculated first band gain and the second band gain to the input audio signal.

3. The method of claim 2, wherein the step of normalizing the audio signal comprises steps of:
measuring a first audio signal size which is a size of an audio signal to which the first and the second band gains have been applied;
scaling the audio signal to which the first and the second band gains have been applied using a preset initial Peek weighting value and measuring a second audio signal size which is a size of the scaled audio signal; and
adjusting the size of the audio signal to which the first and the second band gains have been applied using the first audio signal size, the second audio signal size, and the target audio signal size.

4. A method of adjusting an audio signal size, comprising steps of:
receiving a broadcasting signal;
detecting program genre information in the received broadcasting signal and calculating a third band gain corresponding to the detected program genre information;
detecting an audio signal in the received broadcasting signal and calculating a fourth band gain for normalizing a size of the detected audio signal into a size of a target audio signal; and
applying the calculated third band gain and fourth band gain to the detected audio signal.

5. The method of claim 4, wherein the step of applying the calculated third band gain and fourth band gain to the detected audio signal comprises a step of performing multiplication operation for multiplying the calculated third band gain and the calculated fourth band gain and applying a result of the multiplication operation to the audio signal.
